(19) United States
(12) Patent Application Publication
(10) Pub. No.: US 2024/0361796 A1
(43) Pub. Date: Oct. 31, 2024

(54) REFERENCE VOLTAGE GENERATOR CIRCUIT AND SEMICONDUCTOR INTEGRATED CIRCUIT

(71) Applicant: Socionext Inc., Kanagawa (JP)

(72) Inventors: Yuta IIDA, Kanagawa (JP); Kengo KOMIYA, Kanagawa (JP)

(21) Appl. No.: 18/767,552

(22) Filed: Jul. 9, 2024

Related U.S. Application Data
(63) Continuation of application No. PCT/JP2022/001754, filed on Jan. 19, 2022.

(51) Int. Cl. G05F 3/30

(52) U.S. Cl. CPC G05F 3/30

(57) ABSTRACT

A reference voltage generator circuit includes: a resistor circuit electrically connected between a first node and a second node and between the first node and a third node, the resistor circuit including a variable resistor whose resistance value varies according to a first control signal; a differential amplifier circuit in which one of a differential input pair is electrically connected to the second node and the other of the differential input pair is electrically connected to the third node, the differential amplifier circuit generating a reference voltage at an output node; a current source circuit electrically connected between the second node and a fourth node and between the third node and the fourth node; and an adjuster circuit configured to be electrically connected to the output node, the adjuster circuit configured to generate the first control signal by comparing at least two target voltages with the reference voltage.

### CROSS-REFERENCE TO RELATED APPLICATION

This application is a continuation application of International Application PCT/JP2022/001754 filed on Jan. 19, 2022, and designated the U.S., the entire contents of which are incorporated herein by reference.

### FIELD

The embodiments discussed herein are directed to a reference voltage generator circuit and a semiconductor integrated circuit.

### BACKGROUND

Patent Document 1 has described a reference voltage generating circuit having two bipolar transistors with different current densities, an amplifier circuit that amplifies a voltage of the difference between base-emitter voltages of the two transistors, and a resistor to which the output of the amplifier circuit is applied. A voltage adding circuit adds the voltage generated in the above-described resistor to the base-emitter voltage of one of the above-described two transistors. A regulating resistor is connected in series with the above-described resistor and is capable of regulating a resistance value. A reference voltage regulating unit regulates the reference voltage taken from one end or a midpoint of the above-described regulating resistor.

Patent Document 2 has described a band gap reference voltage generator that includes forward-biased PN junction elements of different current densities. The band gap reference voltage generator includes first and second PN forward-biased junction elements of different current densities, a voltage divider connected to the first PN junction element, and a switch element that selects a voltage divider ratio. A voltage error amplifier receives the divided voltage and the voltage of the second PN junction element and generates a thermally compensated output voltage.

Patent Document 3 has described a band gap voltage reference circuit having high accuracy and low power consumption. The band gap voltage reference circuit includes a high power band gap circuit, a low power band gap circuit, and a calibration circuit. The calibration circuit compares the band gap voltage output by the high power band gap circuit to the band gap voltage output by the low power band gap circuit and outputs a calibration signal to the low power band gap circuit.
[Patent Document 1] Japanese Laid-open Patent Publication No. 2005-182113
[Patent Document 2] U.S. Patent Application Laid-open No. 2014/0070777
[Patent Document 3] U.S. Pat. No. 6,844,711

The reference voltage generator circuit generates a reference voltage. In the reference voltage generator circuit, an error occurs in the reference voltage. To adjust the error, it is necessary to accurately measure the reference voltage. However, it is difficult to accurately measure the reference voltage and adjust the reference voltage with high accuracy.

### SUMMARY

A reference voltage generator circuit includes: a resistor circuit configured to be electrically connected between a first node and a second node and between the first node and a third node, the resistor circuit including a variable resistor whose resistance value varies according to a first control signal; a differential amplifier circuit in which one of a differential input pair is electrically connected to the second node and the other of the differential input pair is electrically connected to the third node, the differential amplifier circuit configured to generate a reference voltage at an output node; a current source circuit configured to be electrically connected between the second node and a fourth node and between the third node and the fourth node; and an adjuster circuit configured to be electrically connected to the output node, the adjuster circuit configured to generate the first control signal by comparing at least two target voltages with the reference voltage.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a diagram illustrating a configuration example of a reference voltage generator circuit according to a comparative example;

FIG. 2 is a diagram illustrating a configuration example of a semiconductor integrated circuit according to a first embodiment;

FIG. 3 is a diagram illustrating another configuration example of the semiconductor integrated circuit according to the first embodiment;

FIG. 4 is a view illustrating a comparison result signal when a reference voltage is lower than two target voltages;

FIG. 5 is a view illustrating a comparison result signal when the reference voltage is the voltage between the two target voltages;

FIG. 6 is a view illustrating a comparison result signal when the reference voltage is higher than the two target voltages;

FIG. 7 is a diagram illustrating a configuration example of a variable resistor;

FIG. 8 is a flowchart for explaining the operation of a reference voltage generator circuit in FIG. 3;

FIG. 9 is a diagram illustrating a configuration example of a semiconductor integrated circuit according to a second embodiment;

FIG. 10 is a diagram illustrating a configuration example of a switch circuit; and

FIG. 11 is a flowchart for explaining the operation of a reference voltage generator circuit in FIG. 9.

### DESCRIPTION OF EMBODIMENTS

### First Embodiment

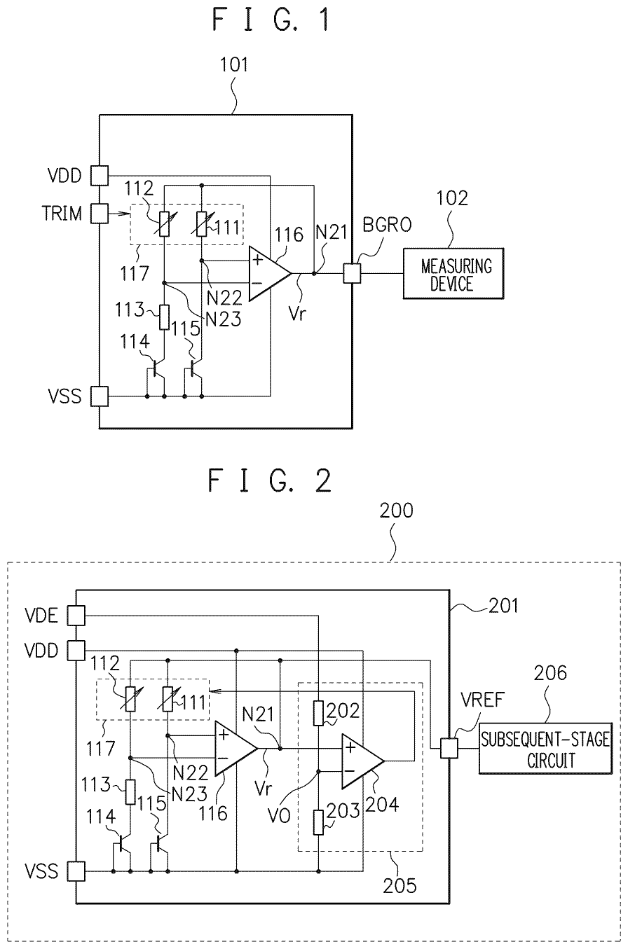

FIG. 1 is a diagram illustrating a configuration example of a reference voltage generator circuit 101. The reference voltage generator circuit 101 is a band gap reference voltage generator circuit, and includes a resistor circuit 117, a resistor 113, pnp-type bipolar transistors 114 and 115, and a differential amplifier circuit 116. The reference voltage generator circuit 101 is a circuit that configures a part of a semiconductor chip, for example and includes a terminal VDD, a terminal TRIM, a terminal VSS, and a terminal BGRO. The terminal VDD receives a power supply voltage. The terminal TRIM receives a trim code. The terminal VSS receives a ground potential. The terminal BGRO outputs a reference voltage Vr.

The resistor circuit 117 includes a variable resistor 111 and a variable resistor 112. The variable resistor 111 is connected between a node N21 and a node N22. The variable resistor 112 is connected between the node N21 and a node N23. The resistance value of the variable resistor 111 and the resistance value of the variable resistor 112 are set to the same value as each other.

The pnp-type bipolar transistor 115 has an emitter thereof connected to the node N22 and has a base and a collector thereof connected to a node of the terminal VSS. The node of the terminal VSS is a ground potential node. The pnp-type bipolar transistor 115 is diode-connected and connected between the node N22 and the node of the terminal VSS.

The resistor 113 is connected between the node N23 and an emitter of the pnp-type bipolar transistor 114. A base and a collector of the pnp-type bipolar transistor 114 are connected to the node of the terminal VSS. The pnp-type bipolar transistor 114 is diode-connected. A series-connected circuit of the resistor 113 and the pnp-type bipolar transistor 114 is connected between the node N23 and the terminal VSS.

The differential amplifier circuit 116 is connected to a node of the terminal VDD and the node of the terminal VSS. The node of the terminal VDD is a power supply voltage node. The differential amplifier circuit 116 has a +input node of one of a differential input pair electrically connected to the node N22 and has a − input node of the other of the differential input pair electrically connected to the node N23, and generates the reference voltage Vr at its output node. The output node of the differential amplifier circuit 116 is electrically connected to the node N21. The node N21 is electrically connected to the terminal BGRO.

The reference voltage generator circuit 101 can generate a reference voltage Vr that is independent of a power supply voltage and temperature. To improve the accuracy of the reference voltage Vr, the reference voltage Vr of the terminal BGRO is measured by a measuring device 102. Based on the measured reference voltage Vr, a trim code is input to the terminal TRIM so that the reference voltage Vr becomes a target voltage. The resistance values of the variable resistors 111 and 112 are adjusted to the values according to the trim code of the terminal TRIM. As a result, the reference voltage Vr is adjusted to the target voltage.

However, when the current of the reference voltage generator circuit 101 is small, that is, when the drive capability of the reference voltage generator circuit 101 is small, the measuring device 102 becomes a load on the reference voltage generator circuit 101. As a result, it is difficult for the measuring device 102 to accurately measure the reference voltage Vr generated by the reference voltage generator circuit 101. Therefore, it is difficult to adjust the reference voltage Vr with high accuracy by the trim code. The embodiment to solve this problem is explained below.

FIG. 2 is a diagram illustrating a configuration example of a semiconductor integrated circuit 200 according to the first embodiment. The semiconductor integrated circuit 200 includes a reference voltage generator circuit 201 and a subsequent-stage circuit 206. The subsequent-stage circuit 206 is connected to a terminal VREF of the reference voltage generator circuit 201. The reference voltage generator circuit 201 is that an adjuster circuit 205 is added to the reference voltage generator circuit 101 in FIG. 1. The reference voltage generator circuit 201 is a circuit that configures a part of a semiconductor chip, for example, and includes a terminal VDE, the terminal VDD, the terminal VSS, and the terminal VREF.

The adjuster circuit 205 includes resistors 202 and 203 and a comparator circuit 204. The terminal VDE receives a power supply voltage. A node of the terminal VDE is the node of the power supply voltage and is a node independent of the node of the terminal VDD. In other words, the power supply voltage of the terminal VDE is a stable power supply voltage that is hardly affected by the noise of the power supply voltage of the terminal VDD caused by the operation of the reference voltage generator circuit 201.

A series-connected circuit of the resistor 202 and the resistor 203 is connected between the terminal VDE and the terminal VSS. A target voltage V0 is the voltage at an interconnection point of the resistor 202 and the resistor 203.

The comparator circuit 204 is connected to the node of the terminal VDD and the node of the terminal VSS. The comparator circuit 204 compares the reference voltage Vr with the target voltage V0. The adjuster circuit 205 controls the resistance values of the variable resistors 111 and 112 so that the reference voltage Vr becomes the same as the target voltage V0. The adjuster circuit 205 maintains the resistance values of the variable resistors 111 and 112 when the reference voltage Vr is the same as the target voltage V0.

Further, the adjuster circuit 205 increases the resistance values of the variable resistors 111 and 112 when the reference voltage Vr is lower than the target voltage V0. Then, the reference voltage Vr increases and approaches the target voltage V0.

Further, the adjuster circuit 205 reduces the resistance values of the variable resistors 111 and 112 when the reference voltage Vr is higher than the target voltage V0. Then, the reference voltage Vr decreases and approaches the target voltage V0.

As above, the adjuster circuit 205 can accurately measure the reference voltage Vr and adjust the reference voltage Vr with high accuracy so that the reference voltage Vr becomes the same as the target voltage V0.

The terminal VREF is connected to the node N21 and outputs the reference voltage Vr. The subsequent-stage circuit 206 operates by receiving the supply of the reference voltage Vr from the terminal VREF of the reference voltage generator circuit 201.

The reference voltage generator circuit 201 can accurately execute trimming adjustments to increase the accuracy of the reference voltage Vr while reducing the amount of drive current flowing to the reference voltage generator circuit 201. Further, in the reference voltage generator circuit 201, it is not necessary to provide the terminal BGRO intended for connecting the external measuring device 102 for trimming adjustment and the output node of the differential amplifier circuit 116, as illustrated in FIG. 1, resulting in that it is possible to reduce the number of terminals in the reference voltage generator circuit 201. Further, it is not necessary to provide the pad, which is intended for connecting with the external measuring device 102, on the semiconductor chip where the reference voltage generator circuit 201 is provided, resulting in that it is possible to reduce the number of pads on the semiconductor chip.

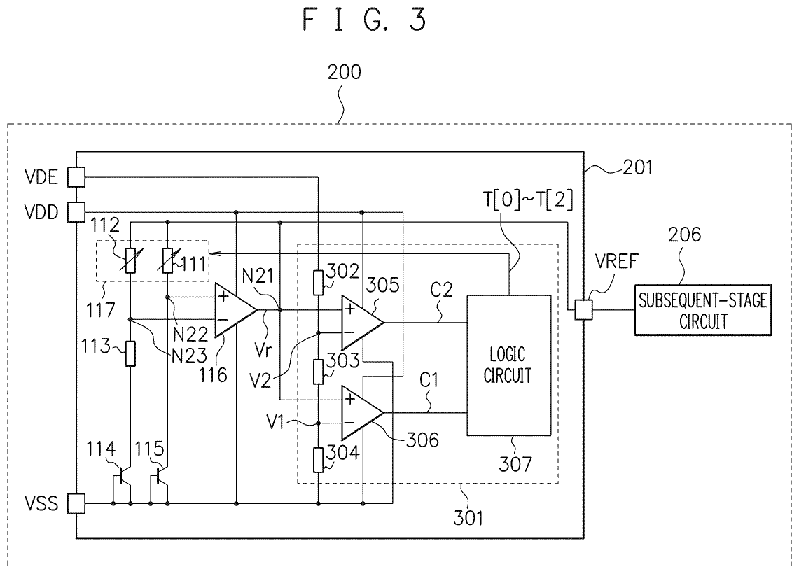

FIG. 3 is a diagram illustrating another configuration example of the semiconductor integrated circuit 200 according to the first embodiment. The semiconductor integrated circuit 200 includes a reference voltage generator circuit 201 and the subsequent-stage circuit 206. The subsequent-stage circuit 206 is connected to the terminal VREF of the reference voltage generator circuit 201. The reference voltage generator circuit 201 in FIG. 3 is that in place of the adjuster circuit 205, an adjuster circuit 301 is added to the reference voltage generator circuit 201 in FIG. 2.

The reference voltage generator circuit 201 is a band gap reference voltage generator circuit, and includes the resistor circuit 117, the resistor 113, the pnp-type bipolar transistors 114 and 115, the differential amplifier circuit 116, and the adjuster circuit 301. The reference voltage generator circuit 201 is a circuit that configures a part of a semiconductor chip, for example and includes the terminal VDE, the terminal VDD, the terminal VSS, and the terminal VREF.

The terminals VDD and VDE receive power supply voltages that are independent of each other. The node of the terminal VDE is the node of the power supply voltage and is a node independent of the node of the terminal VDD. In other words, the power supply voltage of the terminal VDE is a stable power supply voltage that is hardly affected by the noise of the power supply voltage of the terminal VDD caused by the operation of the reference voltage generator circuit 201. The terminal VSS receives the ground potential. The terminal VREF outputs the reference voltage Vr.

The resistor circuit 117 includes the variable resistor 111 and the variable resistor 112. The variable resistor 111 is connected between the node N21 and the node N22. The variable resistor 112 is connected between the node N21 and the node N23. The resistance value of the variable resistor 111 and the resistance value of the variable resistor 112 are set to the same value as each other.

The pnp-type bipolar transistor 115 has an emitter thereof connected to the node N22 and has a base and a collector thereof connected to the node of the terminal VSS. The node of the terminal VSS is the ground potential node. The pnp-type bipolar transistor 115 is diode-connected and connected between the node N22 and the node of the terminal VSS.

The resistor 113 is connected between the node N23 and an emitter of the pnp-type bipolar transistor 114. A base and a collector of the pnp-type bipolar transistor 114 are connected to the node of the terminal VSS. The pnp-type bipolar transistor 114 is diode-connected. A series-connected circuit of the resistor 113 and the pnp-type bipolar transistor 114 is connected between the node N23 and the terminal VSS.

The differential amplifier circuit 116 is connected to the node of the terminal VDD and the node of the terminal VSS. The node of the terminal VDD is the power supply voltage node. The differential amplifier circuit 116 has a +input node of one of a differential input pair electrically connected to the node N22 and has a-input node of the other of the differential input pair electrically connected to the node N23, and generates the reference voltage Vr at its output node. The output node of the differential amplifier circuit 116 is connected to the node N21. The node N21 is connected to the terminal VREF. The reference voltage generator circuit 201 can generate a reference voltage Vr that is independent of the power supply voltage and temperature.

The adjuster circuit 301 includes resistors 302 to 304, comparator circuits 305 and 306, and a logic circuit 307. A series-connected circuit of the resistors 302 to 304 is connected between the terminal VDE and the terminal VSS, and generates target voltages V1 and V2 by resistively dividing the power supply voltage of the terminal VDE. The target voltage V1 is the voltage at an interconnection point of the resistors 303 and 304. The target voltage V2 is the voltage at an interconnection point of the resistors 302 and 303, which is higher than the target voltage V1.

The comparator circuit 306 compares the reference voltage Vr with the target voltage V1 to output a comparison result signal C1. The comparator circuit 305 compares the reference voltage Vr with the target voltage V2 to output a comparison result signal C2.

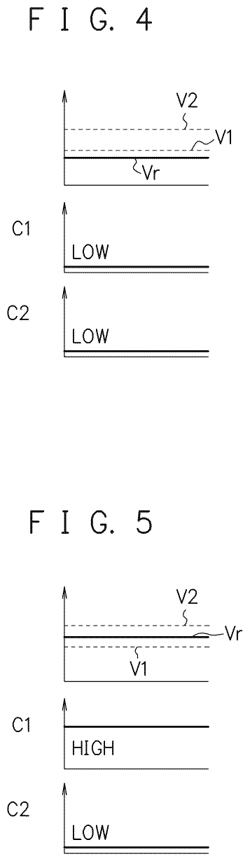

FIG. 4 is a view illustrating the comparison result signals C1 and C2 when the reference voltage Vr is lower than the target voltages V1 and V2. When the reference voltage Vr is lower than the target voltage V1, the comparator circuit 306 outputs the comparison result signal C1 of 0 (low level). When the reference voltage Vr is lower than the target voltage V2, the comparator circuit 305 outputs the comparison result signal C2 of 0 (low level).

FIG. 5 is a view illustrating the comparison result signals C1 and C2 when the reference voltage Vr is the voltage between the target voltage V1 and the target voltage V2. When the reference voltage Vr is higher than the target voltage V1, the comparator circuit 306 outputs the comparison result signal C1 of 1 (high level). When the reference voltage Vr is lower than the target voltage V2, the comparator circuit 305 outputs the comparison result signal C2 of 0 (low level).

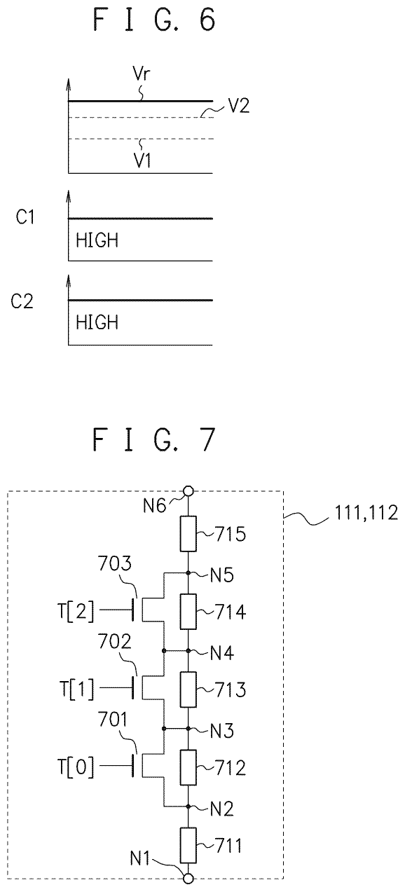

FIG. 6 is a view illustrating the comparison result signals C1 and C2 when the reference voltage Vr is higher than the target voltages V1 and V2. When the reference voltage Vr is higher than the target voltage V1, the comparator circuit 306 outputs the comparison result signal C1 of 1 (high level). When the reference voltage Vr is higher than the target voltage V2, the comparator circuit 305 outputs the comparison result signal C2 of 1 (high level).

The logic circuit 307 outputs, for example, 3-bit trim codes T [0] to T [2] to the variable resistors 111 and 112 according to the comparison result signals C1 and C2.

FIG. 7 is a diagram illustrating a configuration example of each of the variable resistors 111 and 112. The variable resistors 111 and 112 have the same configuration as each other. The variable resistors 111 and 112 each have n-channel field-effect transistors 701 to 703 and resistors 711 to 715.

The resistor 711 is connected between a node N1 and a node N2. The resistor 712 is connected between the node N2 and a node N3. The resistor 713 is connected between the node N3 and a node N4. The resistor 714 is connected between the node N4 and a node N5. The resistor 715 is connected between the node N5 and a node N6.

In the case of the variable resistor 111, the node N1 is connected to the node N22 in FIG. 3, and the node N6 is connected to the node N21 in FIG. 3. In the case of the variable resistor 112, the node N1 is connected to the node N23 in FIG. 3, and the node N6 is connected to the node N21 in FIG. 3.

The n-channel field-effect transistor 701 connects the node N2 to the node N3 when the trim code T [0] is 1, and disconnects the node N2 from the node N3 when the trim code T [0] is 0.

The n-channel field-effect transistor 702 connects the node N3 to the node N4 when the trim code T [1] is 1, and disconnects the node N2 from the node N4 when the trim code T [1] is 0.

The n-channel field-effect transistor 703 connects the node N4 to the node N5 when the trim code T [2] is 1, and disconnects the node N4 from the node N5 when the trim code T [2] is 0.

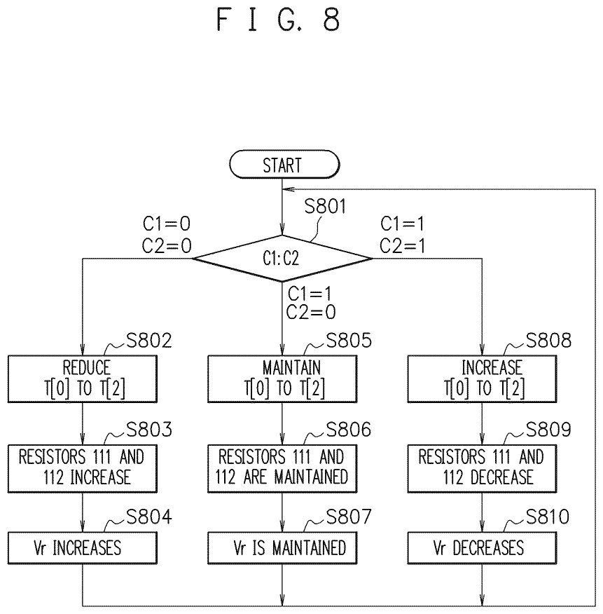

FIG. 8 is a flowchart for explaining the operation of the reference voltage generator circuit 201 in FIG. 3. At Step S801, the logic circuit 307 proceeds to one of Steps S802, S805, and S808 depending on the comparison result signals C1 and C2.

When the comparison result signals C1 and C2 are 0, the logic circuit 307 proceeds to Step S802 because the reference voltage Vr is lower than the target voltages V1 and V2, as illustrated in FIG. 4.

Further, when the comparison result signal C1 is 1 and the comparison result signal C2 is 0, the logic circuit 307 proceeds to Step S805 because the reference voltage Vr is the voltage between the target voltage V1 and the target voltage V2, as illustrated in FIG. 5.

Further, when the comparison result signals C1 and C2 are 1, the logic circuit 307 proceeds to Step S808 because the reference voltage Vr is higher than the target voltages V1 and V2, as illustrated in FIG. 6.

At Step S802, the logic circuit 307 reduces the trim codes T [0] to T [2] by one unit. Specifically, the logic circuit 307 reduces the total number of bits of 1 in the trim codes T [0] to T [2] by one. For example, when the current trim codes T [0] to T [2] are 111, the logic circuit 307 changes the trim codes T [0] to T [2] to 110.

Then, at Step S803, the resistance values of the variable resistors 111 and 112 increase as the trim codes T [0] to T [2] decrease. For example, the resistance values of the variable resistors 111 and 112 when the trim codes T [0] to T [2] are 110 are larger than those of the variable resistors 111 and 112 when the trim codes T [0] to T [2] are 111. The resistance values of the variable resistors 111 and 112 are the same as each other.

Then, at Step S804, the reference voltage Vr output by the differential amplifier circuit 116 increases and approaches the target voltages V1 and V2 as the resistance values of the variable resistors 111 and 112 increase. Thereafter, the processing of the reference voltage generator circuit 201 returns to Step S801.

At Step S805, the logic circuit 307 maintains the current trim codes T [0] to T [2].

Then, at Step S806, the resistance values of the variable resistors 111 and 112 are maintained because the trim codes T [0] to T [2] are maintained. The resistance values of the variable resistors 111 and 112 are the same as each other.

Then, at Step S807, when the resistance values of the variable resistors 111 and 112 are maintained, the reference voltage Vr output by the differential amplifier circuit 116 is maintained. Thereafter, the processing of the reference voltage generator circuit 201 returns to Step S801.

At Step S808, the logic circuit 307 increases the trim codes T [0] to T [2] by one unit. Specifically, the logic circuit 307 increases the total number of bits of 1 in the trim codes T [0] to T [2] by one. For example, when the current trim codes T [0] to T [2] are 000, the logic circuit 307 changes the trim codes T [0] to T [2] to 001.

Then, at Step S809, the resistance values of the variable resistors 111 and 112 decrease as the trim codes T [0] to T [2] increase. For example, the resistance values of the variable resistors 111 and 112 when the trim codes T [0] to T [2] are 001 are smaller than those of the variable resistors 111 and 112 when the trim codes T [0] to T [2] are 000. The resistance values of the variable resistors 111 and 112 are the same as each other.

Then, at Step S810, the reference voltage Vr output by the differential amplifier circuit 116 decreases and approaches the target voltages V1 and V2 as the resistance values of the variable resistors 111 and 112 decrease. Thereafter, the processing of the reference voltage generator circuit 201 returns to Step S801.

As the reference voltage generator circuit 201 performs pieces of the processing of the flowchart in FIG. 8 repeatedly, the reference voltage Vr converges to a voltage between the target voltages V1 and V2. Pieces of the processing of the flowchart in FIG. 8 are performed repeatedly during the period when the power supply voltage is supplied to the reference voltage generator circuit 201. Incidentally, pieces of the processing of the flowchart in FIG. 8 may be performed at the time when the reference voltage generator circuit 201 is shipped from a factory, or as initialization processing when the power supply voltage is started to be supplied to the reference voltage generator circuit 201.

Incidentally, the resistor circuit 117 is not limited to the case where the variable resistors 111 and 112 are provided. The resistor circuit 117 may be the one that is electrically connected between the node N21 and the node N22 and between the node N21 and the node N23, and includes variable resistors whose resistance values vary according to the trim codes (control signals) T [0] to [T2].

Further, the resistor 113 and the pnp-type bipolar transistors 114 and 115 may share a single current source, and only need to be a current source circuit electrically connected between the node N22 and the terminal VSS and between the node N23 and the terminal VSS.

Further, the case of the two target voltages V1 and V2 has been explained as an example, but the number of target voltages may be three or more. Similarly, the case of the two comparator circuits 305 and 306 has been explained as an example, but the number of comparator circuits may be three or more. Similarly, the case of the 3-bit trim codes T [0] to T [2] has been explained as an example, but the trim codes may have 4 bits or more.

The adjuster circuit 301 includes a series-connected circuit of the resistors 302 to 304 that generates at least two target voltages by resistively dividing the power supply voltage of the terminal VDE.

The adjuster circuit 301 is electrically connected to the output node of the differential amplifier circuit 116 and compares at least the two target voltages V1 and V2 with the reference voltage Vr, to thereby generate the trim codes T [0] to T [2].

As illustrated in FIG. 4, the resistor circuit 117 increases the resistance value between the node N21 and the node N22 and the resistance value between the node N21 and the node N23 when the reference voltage Vr is lower than the target voltage V1 and the target voltage V2.

As illustrated in FIG. 5, when the reference voltage Vr is the voltage between the target voltage V1 and the target voltage V2, the resistor circuit 117 maintains the resistance value between the node N21 and the node N22 and the resistance value between the node N21 and the node N23.

As illustrated in FIG. 6, when the reference voltage Vr is higher than the target voltage V1 and the target voltage V2, the resistor circuit 117 reduces the resistance value between the node N21 and the node N22 and the resistance value between the node N21 and the node N23.

The resistor circuit 117 has the resistance value between the node N21 and the node N22 and the resistance value between the node N21 and the node N23 that are the same as each other.

The comparator circuit 305 and the comparator circuit 306 operate by receiving the supply of the power supply voltage from the node of the terminal VDD, which is independent of the node of the power supply voltage of the terminal VDE. That is, the power supply voltage of the terminal VDE is a stable power supply voltage that is hardly affected by the noise of the power supply voltage of the terminal VDD caused by the operation of the reference voltage generator circuit 201.

The logic circuit 307 generates the trim codes T [0] to T [2] according to the comparison result signal (output signal) C1 of the comparator circuit 306 and the comparison result signal (output signal) C2 of the comparator circuit 305.

As above, the reference voltage generator circuit 201 can accurately execute trimming adjustments to increase the accuracy of the reference voltage Vr while reducing the amount of drive current flowing to the reference voltage generator circuit 201. Further, in the reference voltage generator circuit 201, it is not necessary to provide the terminal BGRO intended for connecting the external measuring device 102 for trimming adjustment and the output node of the differential amplifier circuit 116, as illustrated in FIG. 1, resulting in that it is possible to reduce the number of terminals in the reference voltage generator circuit 201. Further, it is not necessary to provide the pad, which is intended for connecting with the external measuring device 102, on the semiconductor chip where the reference voltage generator circuit 201 is provided, resulting in that it is possible to reduce the number of pads on the semiconductor chip.

### Second Embodiment

Since the adjuster circuit 301 in FIG. 3 automatically adjusts the reference voltage Vr, there is a concern that the reference voltage Vr is supplied to the subsequent-stage circuit 206 even when the reference voltage Vr is not the voltage between the target voltages V1 and V2, resulting in erroneous operation of the subsequent-stage circuit 206. This problem is a problem that has arisen newly as a result of the adjuster circuit 301 automatically adjusting the reference voltage Vr. In order for the adjuster circuit 301 to automatically adjust the reference voltage Vr, it is necessary to have a mechanism to supply the reference voltage Vr to the subsequent-stage circuit 206 after the reference voltage Vr is determined to become the voltage between the target voltages V1 and V2. There is explained a second embodiment for solving this problem below.

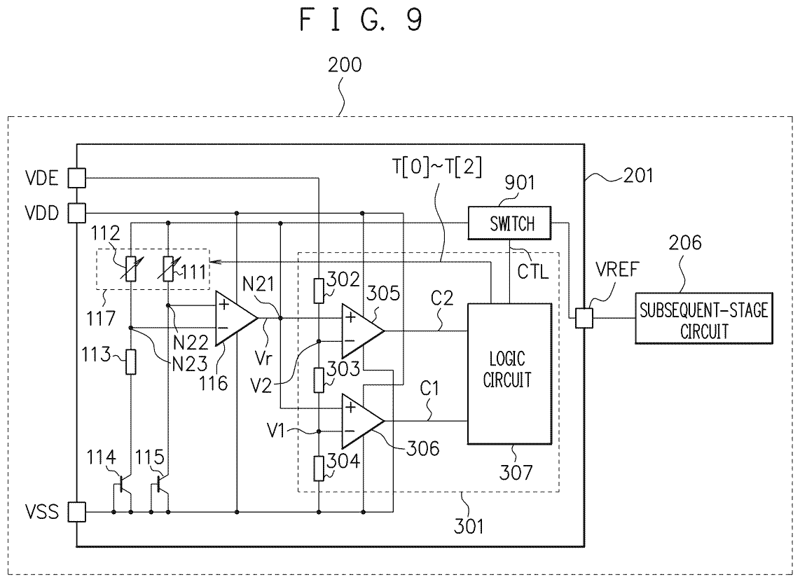

FIG. 9 is a diagram illustrating a configuration example of a semiconductor integrated circuit 200 according to the second embodiment. The semiconductor integrated circuit 200 in FIG. 9 is that a switch circuit 901 is added to the semiconductor integrated circuit 200 in FIG. 3. The differences of FIG. 9 from FIG. 3 are explained below.

The reference voltage generator circuit 201 includes the switch circuit 901. The switch circuit 901 is connected between the node N21 and the terminal VREF and connects the node N21 to the terminal VREF according to a control signal CTL. The terminal VREF is a reference voltage node intended for outputting the reference voltage. The adjuster circuit 301 generates the control signal CTL according to a result of comparison between at least the two target voltages V1 and V2 and the reference voltage Vr.

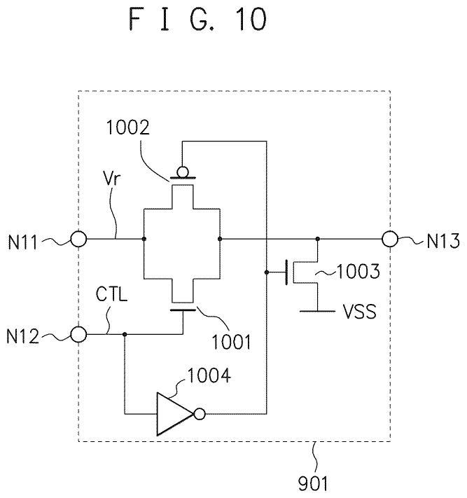

FIG. 10 is a diagram illustrating a configuration example of the switch circuit 901 in FIG. 9. The switch circuit 901 includes an n-channel field-effect transistor 1001, a p-channel field-effect transistor 1002, an n-channel field-effect transistor 1003, and an inverter 1004.

A node N11 is connected to the node N21 in FIG. 9, and receives the reference voltage Vr. A node N12 receives the control signal CTL of the logic circuit 307 in FIG. 9. A node N13 is connected to the terminal VREF in FIG. 9. The inverter 1004 outputs a logically inverted signal of the control signal CTL.

The n-channel field-effect transistor 1001 has a source thereof connected to the node N11, has a gate thereof connected to the node N12, and has a drain thereof connected to the node N13. The p-channel field-effect transistor 1002 has a source thereof connected to the node N11, has a gate thereof connected to an output node of the inverter 1004, and has a drain thereof connected to the node N13. The n-channel field-effect transistor 1003 has a drain thereof connected to the node N13, has a gate thereof connected to the output node of the inverter 1004, and has a source thereof connected to the terminal VSS.

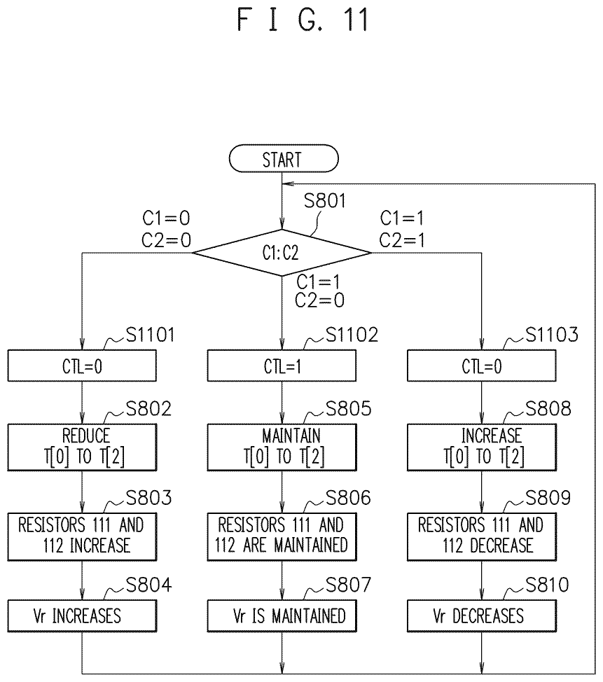

FIG. 11 is a flowchart for explaining the operation of the reference voltage generator circuit 201 in FIG. 9. The flowchart in FIG. 11 is that Steps S1101 to S1103 are added to the flowchart in FIG. 8. The differences of FIG. 11 from FIG. 8 are explained below.

At Step S801, the logic circuit 307 proceeds to one of Steps S1101 to S1103 depending on the comparison result signals C1 and C2.

As illustrated in FIG. 4, when the comparison result signals C1 and C2 are 0, the logic circuit 307 proceeds to Step S1101 because the reference voltage Vr is lower than the target voltages V1 and V2.

Further, when the comparison result signal C1 is 1 and the comparison result signal C2 is 0, the logic circuit 307 proceeds to Step S1102 because the reference voltage Vr is the voltage between the target voltage V1 and the target voltage V2, as illustrated in FIG. 5.

Further, when the comparison result signals C1 and C2 are 1, the logic circuit 307 proceeds to Step S1103 because the reference voltage Vr is higher than the target voltages V1 and V2, as illustrated in FIG. 6.

At Step S1101, the logic circuit 307 outputs the control signal CTL of 0 to the switch circuit 901. Then, as illustrated in FIG. 10, the n-channel field-effect transistor 1001 and the p-channel field-effect transistor 1002 are turned off, and the n-channel field-effect transistor 1003 is turned on. The node N11 (node N21) is disconnected from the node N13 (terminal VREF). The node N13 (terminal VREF) is connected to the terminal VSS (ground potential node). The terminal VREF does not become the reference voltage Vr, but becomes the ground potential. The terminal VREF of the reference voltage generator circuit 201 does not supply the reference voltage Vr to the subsequent-stage circuit 206. Thereafter, the processing of the reference voltage generator circuit 201 proceeds to Steps S802 to S804 as in FIG. 8.

At Step S1102, the logic circuit 307 outputs the control signal CTL of 1 to the switch circuit 901. Then, as illustrated in FIG. 10, the n-channel field-effect transistor 1001 and the p-channel field-effect transistor 1002 are turned on, and the n-channel field-effect transistor 1003 is turned off. The node N11 (node N21) is connected to the node N13 (terminal VREF). The node N13 (terminal VREF) is disconnected from the terminal VSS (ground potential node). The terminal VREF becomes the reference voltage Vr. The terminal VREF of the reference voltage generator circuit 201 supplies the reference voltage Vr to the subsequent-stage circuit 206. Thereafter, the processing of the reference voltage generator circuit 201 proceeds to Steps S805 to S807, as in FIG. 8.

At Step S1103, the logic circuit 307 outputs the control signal CTL of 0 to the switch circuit 901. Then, as illustrated in FIG. 10, the n-channel field-effect transistor 1001 and the p-channel field-effect transistor 1002 are turned off, and the n-channel field-effect transistor 1003 is turned on. The node N11 (node N21) is disconnected from the node N13 (terminal VREF). The node N13 (terminal VREF) is connected to the terminal VSS (ground potential node). The terminal VREF does not become the reference voltage Vr, but becomes the ground potential. The terminal VREF of the reference voltage generator circuit 201 does not supply the reference voltage Vr to the subsequent-stage circuit 206. Thereafter, the processing of the reference voltage generator circuit 201 proceeds to Steps S808 to S810 as in FIG. 8.

As above, at Step S1102, the switch circuit 901 connects the node N21 to the terminal VREF when the reference voltage Vr is the voltage between the target voltage V1 and the target voltage V2.

At Steps S1101 and S1103, the switch circuit 901 disconnects the node N21 from the terminal VREF when the reference voltage Vr is not the voltage between the target voltage V1 and the target voltage V2. When disconnecting the node N21 from the terminal VREF, the switch circuit 901 connects the terminal VREF to the terminal VSS (ground potential node).

According to this embodiment, when the reference voltage Vr is not the voltage between the target voltage V1 and the target voltage V2, the switch circuit 901 is turned off and does not supply the reference voltage Vr to the subsequent-stage circuit 206. This makes it possible to prevent the erroneous operation of the subsequent-stage circuit 206.

Incidentally, the above-described embodiments merely illustrate concrete examples of implementing the present invention, and the technical scope of the present invention is not to be construed in a restrictive manner by the embodiments. That is, the present invention may be implemented in various forms without departing from the technical spirit or main features thereof.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

It is possible to adjust the generated reference voltage with high accuracy.

What is claimed is:

1. A reference voltage generator circuit, comprising:
a resistor circuit configured to be electrically connected between a first node and a second node and between the first node and a third node, the resistor circuit including a variable resistor whose resistance value varies according to a first control signal;
a differential amplifier circuit in which one of a differential input pair is electrically connected to the second node and the other of the differential input pair is electrically connected to the third node, the differential amplifier circuit configured to generate a reference voltage at an output node;
a current source circuit configured to be electrically connected between the second node and a fourth node and between the third node and the fourth node; and
an adjuster circuit configured to be electrically connected to the output node, the adjuster circuit configured to generate the first control signal by comparing at least two target voltages with the reference voltage.

2. The reference voltage generator circuit according to claim 1, further comprising:
a switch circuit configured to connect the output node to a reference voltage node according to a second control signal, the reference voltage node being a node for outputting the reference voltage node, wherein
the adjuster circuit is configured to generate the second control signal according to a result of comparison between the at least two target voltages and the reference voltage.

3. The reference voltage generator circuit according to claim 2, wherein
the switch circuit is configured to connect the reference voltage node to a ground potential node when disconnecting the output node from the reference voltage node.

4. The reference voltage generator circuit according to claim 2, wherein
the at least two target voltages include a first target voltage and a second target voltage, and
the switch circuit is configured to connect the output node to the reference voltage node when the reference voltage is a voltage between the first target voltage and the second target voltage, and the switch circuit is configured to disconnect the output node from the reference voltage node when the reference voltage is not a voltage between the first target voltage and the second target voltage.

5. The reference voltage generator circuit according to claim 1, wherein
the resistor circuit includes:
a first variable resistor configured to be connected between the first node and the second node; and
a second variable resistor configured to be connected between the first node and the third node.

6. The reference voltage generator circuit according to claim 1, wherein
the at least two target voltages include a first target voltage and a second target voltage, and
the resistor circuit is configured to increase a resistance value between the first node and the second node and a resistance value between the first node and the third node when the reference voltage is lower than the first target voltage and the second target voltage,
the resistor circuit is configured to maintain the resistance value between the first node and the second node and the resistance value between the first node and the third node when the reference voltage is a voltage between the first target voltage and the second target voltage, and
the resistor circuit is configured to reduce the resistance value between the first node and the second node and the resistance value between the first node and the third node when the reference voltage is higher than the first target voltage and the second target voltage.

7. The reference voltage generator circuit according to claim 1, wherein
in the resistor circuit, the resistance value between the first node and the second node and the resistance value between the first node and the third node are configured to be the same as each other.

8. The reference voltage generator circuit according to claim 1, wherein
the current source circuit includes:
a first transistor configured to be connected between the second node and the fourth node; and
a first resistor and a second transistor configured to be connected between the third node and the fourth node, and
the first transistor and the second transistor are each configured to be diode connected.

9. The reference voltage generator circuit according to claim 1, wherein
the fourth node is a ground potential node.

10. The reference voltage generator circuit according to claim 1, wherein
the output node is configured to be electrically connected to the first node.

11. The reference voltage generator circuit according to claim 1, wherein
the at least two target voltages include a first target voltage and a second target voltage, and
the adjuster circuit includes:
a first comparator circuit configured to compare the reference voltage with the first target voltage; and
a second comparator circuit configured to compare the reference voltage with the second target voltage.

12. The reference voltage generator circuit according to claim 1, wherein
the adjuster circuit includes a resistor series-connected circuit configured to generate the at least two target voltages by resistively dividing a first power supply voltage.

13. The reference voltage generator circuit according to claim 11, wherein
the adjuster circuit includes a resistor series-connected circuit configured to generate the at least two target voltages by resistively dividing a first power supply voltage, and
the first comparator circuit and the second comparator circuit are configured to operate by receiving supply of a second power supply voltage from a node independent of a node from which the first power supply voltage is configured to be supplied.

14. The reference voltage generator circuit according to claim 11, wherein
the adjuster circuit includes a logic circuit configured to generate the first control signal according to an output signal of the first comparator circuit and an output signal of the second comparator circuit.

15. A semiconductor integrated circuit, comprising:
a reference voltage generator circuit; and
a first circuit configured to be connected to the reference voltage generator circuit, wherein
the reference voltage generator circuit includes:
a resistor circuit configured to be electrically connected between a first node and a second node and between the first node and a third node, the resistor circuit including a variable resistor whose resistance value varies according to a first control signal;
a differential amplifier circuit in which one of a differential input pair is electrically connected to the second node and the other of the differential input pair is electrically connected to the third node, the differential amplifier circuit configured to generate a reference voltage at an output node;
a current source circuit configured to be electrically connected between the second node and a fourth node and between the third node and the fourth node; and
an adjuster circuit configured to be electrically connected to the output node, the adjuster circuit configured to generate the first control signal by comparing at least two target voltages with the reference voltage, and
the first circuit is configured to operate by receiving supply of the reference voltage from the reference voltage generator circuit.

16. The semiconductor integrated circuit according to claim 15, wherein
the reference voltage generator circuit further includes a switch circuit configured to connect the output node to a reference voltage node according to a second control signal, the reference voltage node being a node for outputting the reference voltage, and
the adjuster circuit is configured to generate the second control signal according to a result of comparison between the at least two target voltages and the reference voltage.

17. The semiconductor integrated circuit according to claim 16, wherein
the at least two target voltages include a first target voltage and a second target voltage, and
the switch circuit is configured to connect the output node to the reference voltage node when the reference voltage is a voltage between the first target voltage and the second target voltage, and the switch circuit is configured to disconnect the output node from the reference voltage node when the reference voltage is not a voltage between the first target voltage and the second target voltage.

18. The semiconductor integrated circuit according to claim 15, wherein
the at least two target voltages include a first target voltage and a second target voltage, and
the resistor circuit is configured to increase a resistance value between the first node and the second node and a resistance value between the first node and the third node when the reference voltage is lower than the first target voltage and the second target voltage,
the resistor circuit is configured to maintain the resistance value between the first node and the second node and the resistance value between the first node and the third node when the reference voltage is a voltage between the first target voltage and the second target voltage, and
the resistor circuit is configured to reduce the resistance value between the first node and the second node and the resistance value between the first node and the third node when the reference voltage is higher than the first target voltage and the second target voltage.

19. The semiconductor integrated circuit according to claim 15, wherein
the at least two target voltages include a first target voltage and a second target voltage, and
the adjuster circuit includes:
a first comparator circuit configured to compare the reference voltage with the first target voltage; and
a second comparator circuit configured to compare the reference voltage with the second target voltage.

20. The semiconductor integrated circuit according to claim 19, wherein
the adjuster circuit includes a resistor series-connected circuit configured to generate the at least two target voltages by resistively dividing a first power supply voltage, and
the first comparator circuit and the second comparator circuit are configured to operate by receiving supply of a second power supply voltage from a node independent of a node from which the first power supply voltage is configured to be supplied.
